(19) United States
(12) Patent Application Publication
(10) Pub. No.: US 2021/0050540 A1
(43) Pub. Date: Feb. 18, 2021

(54) STACKED BULK HETEROJUNCTION SOLAR CELLS FOR BROADBAND AND TAILORABLE SPECTRAL COVERAGE

(71) Applicant: Ubiquitous Energy, Inc., Redwood City, CA (US)

(72) Inventors: Miles C. Barr, Redwood City, CA (US); Richa Pandey, Sunnyvale, CA (US); Matthew E. Sykes, San Mateo, CA (US); John A. Love, Mountain View, CA (US)

(73) Assignee: Ubiquitous Energy, Inc., REDWOOD CITY, CA (US)

(21) Appl. No.: 16/994,363

(22) Filed: Aug. 14, 2020

Related U.S. Application Data
(60) Provisional application No. 62/887,973, filed on Aug. 16, 2019.

(51) Int. Cl. H01L 51/42; H01L 51/44; H01L 27/30

(52) U.S. Cl. CPC H01L 51/4273; H01L 27/302; H01L 51/442

(57) ABSTRACT

Visibly transparent photovoltaic devices having bulk heterojunctions (BHJ) are disclosed. Such devices are transparent to visible light but absorb near-infrared light and/or ultraviolet light. The photovoltaic devices may include bottom and top visibly transparent electrodes, as well as multiple stacked BHJ active layers that have complementary absorption characteristics. For example, a first BHJ active layer may have an absorption spectrum that is complementary to an absorption spectrum of a second BHJ active layer.

### CROSS-REFERENCES TO RELATED APPLICATIONS

This application claims the benefit of priority to U.S. Provisional Patent Application No. 62/887,973, filed Aug. 16, 2019, entitled “STACKED BULK HETEROJUNCTION SOLAR CELLS FOR BROADBAND AND TAILORABLE SPECTRAL COVERAGE,” the entire content of which is incorporated herein by reference for all purposes.

### BACKGROUND OF THE INVENTION

Photovoltaic devices are commonly employed to convert light into electricity by using the photovoltaic effect, in which absorbed light causes the excitation of an electron or other charge carrier to a higher-energy state. The separation of charge carriers of opposite types leads to a voltage that can be utilized by an external circuit. Photovoltaic devices, such as photovoltaic solar cells, can be packaged together to constitute a photovoltaic array of a larger photovoltaic system, such as a solar panel. The use of photovoltaic systems to generate electricity is an important form of renewable energy that continues to become a mainstream electricity source worldwide.

The surface area necessary to take advantage of solar energy remains an obstacle to offsetting a significant portion of non-renewable energy consumption. For this reason, low-cost, transparent, organic photovoltaic (OPV) devices that can be integrated onto window panes in homes, skyscrapers, and automobiles are desirable. For example, window glass utilized in automobiles and architecture are typically 70-80% and 40-80% transmissive, respectively, to the visible spectrum, e.g., light with wavelengths from about 450 to 650 nm. The low mechanical flexibility, high module cost and, more importantly, the band-like absorption of inorganic semiconductors limit their potential utility to transparent solar cells. Despite the progress made, there is a need in the art for improved systems, methods, and device structures in the field of transparent solar technology.

### SUMMARY OF THE INVENTION

Transparent organic photovoltaic (OPV) devices that can be integrated onto windows panes are desirable for providing large surface areas to take advantage of solar energy. In contrast to inorganic semiconductors, the optical characteristics of organic and molecular semiconductors result in absorption spectra that are highly structured with absorption minima and maxima that are uniquely distinct from the band absorption of their inorganic counterparts. However, while a variety of organic and molecular semiconductors exist, many exhibit strong absorption in the visible spectrum and thus are not optimal for use in window glass-based photovoltaics.

This application relates generally to the field of optically active materials and devices, and, more particularly, to visibly transparent and visibly opaque photovoltaic devices and materials for visibly transparent and visibly opaque photovoltaic devices.

Described herein are materials, methods, and systems related to visibly transparent and visibly opaque photovoltaic devices. More particularly, the present description provides visibly transparent and visibly opaque photovoltaic devices having one or more bulk heterojunction (BHJ) active layers disposed between visibly transparent electrodes.

A summary of the present invention is provided in reference to various examples given below. As used below, any reference to a series of examples is to be understood as a reference to each of those examples disjunctively (e.g., “Examples 1-4” is to be understood as “Examples 1, 2, 3, or 4”).

Example 1 is an organic photovoltaic device comprising: a substrate; a first electrode coupled to the substrate; a second electrode disposed above the first electrode; a first bulk heterojunction (BHJ) active layer disposed between the first electrode and the second electrode, wherein the first BHJ active layer comprises a first blend of a first electron donor material and a first electron acceptor material; and a second BHJ active layer disposed between the first electrode and the second electrode, wherein the second BHJ active layer comprises a second blend of a second electron donor material and a second electron acceptor material, and wherein the second BHJ active layer is in contact with the first BHJ active layer; wherein an absorption spectrum of the first BHJ active layer is at least partially complementary to an absorption spectrum of the second BHJ active layer.

Example 2 is the organic photovoltaic device of example(s) 1, wherein the first electron donor material is different than the second electron donor material, and wherein the first electron acceptor material is different than the second electron acceptor material.

Example 3 is the organic photovoltaic device of example(s) 1, wherein the first electron donor material is different than the second electron donor material, and wherein the first electron acceptor material is the same as the second electron acceptor material.

Example 4 is the organic photovoltaic device of example(s) 1, wherein the first electron donor material is the same as the second electron donor material, and wherein the first electron acceptor material is different than the second electron acceptor material.

Example 5 is the organic photovoltaic device of example(s) 1, wherein the first electron donor material is the same as the second electron donor material, and wherein the first electron acceptor material is the same as the second electron acceptor material.

Example 6 is the organic photovoltaic device of example(s) 1, wherein a lowest unoccupied molecular orbital (LUMO) energy level of the first BHJ active layer is greater than a LUMO energy level of the second BHJ active layer.

Example 7 is the organic photovoltaic device of example(s) 1, wherein a highest occupied molecular orbital (HOMO) energy level of the second BHJ active layer is less than a HOMO energy level of the first BHJ active layer.

Example 8 is the organic photovoltaic device of example(s) 1, wherein a lowest unoccupied molecular orbital (LUMO) energy level of the first electron acceptor material of the first BHJ active layer is within 300 meV of a LUMO energy level of the second electron acceptor material of the second BHJ active layer.

Example 9 is the organic photovoltaic device of example(s) 1, wherein a highest occupied molecular orbital (HOMO) energy level of the first electron donor material of the first BHJ active layer is within 300 meV of a HOMO energy level of the second electron donor material of the second BHJ active layer.

Example 10 is the organic photovoltaic device of example(s) 1, wherein the first BHJ active layer is coupled to the second BHJ active layer.

Example 11 is the organic photovoltaic device of example(s) 1, wherein the first blend is a ternary, quaternary, or higher-order blend that includes at least one of an additional electron donor material or an additional electron acceptor material.

Example 12 is the organic photovoltaic device of example(s) 1, wherein the second blend is a ternary, quaternary, or higher-order blend that includes at least one of an additional electron donor material or an additional electron acceptor material.

Example 13 is the organic photovoltaic device of example(s) 1, wherein the first BHJ active layer is coupled to the first electrode.

Example 14 is the organic photovoltaic device of example(s) 1, wherein the second BHJ active layer is coupled to the second electrode.

Example 15 is an organic photovoltaic device comprising: a visibly transparent substrate; a first visibly transparent electrode coupled to the visibly transparent substrate; a second visibly transparent electrode disposed above the first visibly transparent electrode; a first bulk heterojunction (BHJ) active layer disposed between the first visibly transparent electrode and the second visibly transparent electrode, wherein the first BHJ active layer comprises a first blend of a first electron donor material and a first electron acceptor material; and a second BHJ active layer disposed between the first visibly transparent electrode and the second visibly transparent electrode, wherein the second BHJ active layer comprises a second blend of a second electron donor material and a second electron acceptor material, and wherein the second BHJ active layer is in contact with the first BHJ active layer; wherein an absorption spectrum of the first BHJ active layer is at least partially complementary to an absorption spectrum of the second BHJ active layer.

Example 16 is a tandem organic photovoltaic device comprising: a substrate; a first electrode coupled to the substrate; a second electrode disposed above the first electrode; a first subcell disposed between the first electrode and the second electrode, the first subcell comprising: a first bulk heterojunction (BHJ) active layer comprising a first blend of a first electron donor material and a first electron acceptor material; and a second BHJ active layer comprising a second blend of a second electron donor material and a second electron acceptor material, wherein the second BHJ active layer is in contact with the first BHJ active layer, and wherein an absorption spectrum of the first BHJ active layer is at least partially complementary to an absorption spectrum of the second BHJ active layer; a second subcell disposed between the first electrode and the second electrode, the second subcell comprising: a third BHJ active layer comprising a third blend of a third electron donor material and a third electron acceptor material; and a charge recombination zone disposed between the first subcell and the second subcell.

Example 17 is the tandem organic photovoltaic device of example(s) 16, wherein the first subcell is disposed between the first electrode and the charge recombination zone.

Example 18 is the tandem organic photovoltaic device of example(s) 16, wherein the second subcell is disposed between the first electrode and the charge recombination zone.

Example 19 is the tandem organic photovoltaic device of example(s) 16, wherein the second subcell further comprises a fourth BHJ active layer comprising a fourth blend of a fourth electron donor material and a fourth electron acceptor material, wherein the fourth BHJ active layer is in contact with the third BHJ active layer, and wherein the absorption spectrum of the fourth BHJ active layer is at least partially complementary to the absorption spectrum of the third BHJ active layer.

Example 20 is the tandem organic photovoltaic device of example(s) 16, wherein the tandem organic photovoltaic device is visibly transparent.

Example 21 is the tandem organic photovoltaic device of example(s) 16, wherein the tandem organic photovoltaic device is visibly opaque.

Example 22 is the organic photovoltaic device of example(s) 6, wherein the LUMO energy level of the second BHJ active layer is greater than an energy level of the second electrode.

Example 23 is the organic photovoltaic device of example(s) 7, wherein the HOMO energy level of the first BHJ active layer is less than an energy level of the first electrode.

Example 24 is the organic photovoltaic device of example(s) 1, wherein the organic photovoltaic device is visibly transparent.

Example 25 is the organic photovoltaic device of example(s) 1, wherein the organic photovoltaic device is visibly opaque.

Example 26 is the organic photovoltaic device of example(s) 1, further comprising: an exciton-blocking layer, a hole-blocking layer, or an electron-blocking layer disposed between the second BHJ active layer and the second electrode.

Example 27 is the organic photovoltaic device of example(s) 1, further comprising: an exciton-blocking layer, a hole-blocking layer, or an electron-blocking layer disposed between the first electrode and the first BHJ active layer.

Numerous benefits are achieved by way of the present invention over conventional techniques. For example, embodiments of the present invention provide methods and systems for absorbing near-infrared and/or ultraviolet radiation for photovoltaic power generation while being transparent to visible light. Advantageously, these optical characteristics provide for the ability to generate electricity from incident solar radiation in a photovoltaic device, while still allowing useful visible light to be passed through, permitting a viewer to see through the photovoltaic device.

Unlike a tandem photovoltaic device, embodiments of the present invention include no charge recombination zone between multiple BHJ layers. As a result, the photocurrents (not voltages) are additive between the BHJ layers. By incorporating at least one unique active layer material into each BHJ layer, the absorption of the organic photovoltaic (OPV) can be easily tailored for a desired spectral coverage. The stacked BHJ is advantageous over the planar-mixed heterojunction architecture due to the planar layers within the planar-mixed heterojunction being exciton diffusion-limited in thickness. By replacing these planar layers with additional BHJ blends, this limitation can be removed. The stacked BHJ itself is also compatible with planar-mixed junctions, in which the mixed junction can be split into multiple distinct BHJ layers instead of just one.

Unlike single BHJ layers comprised of ternary or higher-order blends, the stacked BHJ separates some of these active materials into discrete layers. As an example, a ternary blend BHJ may instead be split into a stacked BHJ of two binary blends which in combination contain the three materials of the single ternary blend. The use of two binary blends offers significant advantages in terms of simplicity of device optimization, the capability to independently control blend morphology and opto-electrical properties of the materials in each layer, and a simpler deposition process lending to easier manufacturing. Furthermore, in some embodiments, stacked BHJ performance may be enhanced over that of the analogous ternary blend BHJ. The stacked BHJ itself is also compatible with higher-order blends, in which each BHJ layer may comprise two or more active materials.

Furthermore, compared to a tandem architecture electrically connected in series, the stacked BHJ enables higher levels of photocurrent density due to the BHJ layers being current-additive. In applications such as transparent PV where haze or off-angle performance are issues, this may be a promising alternative approach. However, just as is the case with ternary or planar-mixed heterojunctions, the stacked BHJ is compatible with the series tandem architecture. Each series-connected subcell within the series tandem may itself be comprised of a stacked BHJ. This approach can provide greater flexibility for current matching individual subcells for broader spectral coverage.

These and other embodiments and aspects of the invention along with many of its advantages and features are described in more detail in conjunction with the text below and attached figures.

### BRIEF DESCRIPTION OF THE DRAWINGS

FIG. 1 illustrates a simplified schematic diagram of a visibly transparent photovoltaic device according to an embodiment of the present invention.

FIG. 2 illustrates an overview of various example single junction configurations for a photoactive layer.

FIG. 3 illustrates a simplified plot of the solar spectrum, human eye sensitivity, and exemplary visibly transparent photovoltaic device absorption as a function of wavelength.

FIG. 4 illustrates a schematic energy level diagram overview for operation of an example organic photovoltaic device, such as a visibly transparent photovoltaic device.

FIGS. 5A-5D illustrate various plots showing example absorption bands for different electron donor and electron acceptor configurations useful with visibly transparent photovoltaic devices.

FIG. 6 illustrates a device structure, according to an embodiment of the present invention.

FIGS. 7A-7D illustrate various energy level diagrams, according to various embodiments of the present invention.

FIGS. 8A-8C illustrated absorption coefficients for exemplary active layer materials that can be utilized in various embodiments of the present invention.

FIGS. 9A-9C illustrate various device structures, according to various embodiments of the present invention.

FIGS. 10A and 10B illustrate current density-voltage and external quantum efficiency (EQE) curves.

FIGS. 11A-11D illustrate various device structures, according to various embodiments of the present invention.

FIGS. 12A and 12B illustrate current density-voltage and EQE curves.

FIG. 13 illustrates a device structure, according to an embodiment of the present invention.

FIGS. 14A and 14B illustrate current density-voltage and EQE curves.

FIG. 15 illustrates a device structures, according to an embodiment of the present invention.

FIGS. 16A-16C illustrate current density-voltage and EQE curves.

FIG. 17 illustrates a device structure, according to an embodiment of the present invention.

FIG. 18 illustrates a method for making a photovoltaic device.

### DETAILED DESCRIPTION OF SPECIFIC EMBODIMENTS

The present disclosure relates to organic photovoltaic devices (OPVs), and in some embodiments, visibly transparent photovoltaic devices incorporating visibly transparent photoactive compounds. The visibly transparent photoactive compounds absorb light more strongly in the near-infrared and/or ultraviolet regions and less strongly in the visible region, permitting their use in visibly transparent photovoltaic devices. The disclosed visibly transparent photovoltaic devices include visibly transparent electrodes with visibly transparent photoactive materials positioned between the visibly transparent electrodes.

The present disclosure describes the concept of a “stacked” bulk heterojunction (BHJ) in which multiple BHJ blends are layered directly on top of one another within the active layers of an OPV. The use of multiple BHJs with complementary absorbers enables a broadband coverage of the solar spectrum. The photocurrent from each BHJ layer is additive while the voltage is an average of the individual layers in such a structure, in contrast to the standard series connected tandem PV in which subcell currents are matched and voltages are additive. Each discrete BHJ layer may be binary, ternary, or a higher order blend of donors and acceptors.

Neighboring BHJ layers may even share the same acceptor or donor, such that only the donor species or acceptor species is varied between them. Donor and acceptor molecules in adjacent BHJ layers can be selected such that their highest occupied molecular orbital (HOMO) (for donors) or lowest unoccupied molecular orbital (LUMO) (for acceptors) levels are all within ˜300 meV of one another to avoid significant energetic barriers for charge extraction or injection. By reducing barrier height, embodiments of the present invention can reduce or eliminate “s-kinks” and improve device fill factors.

The concept of the BHJ can be used to circumvent the tradeoff between active layer thickness and exciton diffusion efficiency that is intrinsic to planar heterojunctions. As active layer thicknesses are increased above their exciton diffusion length, the efficiency of photo-generated excitons reaching the donor-acceptor interface drops. As a result, active layer thicknesses and light absorption are constrained. By blending both donor and acceptor materials three-dimensionally within a BHJ, the active layer thickness is decoupled from exciton diffusion efficiency; instead the morphology of individual donor and acceptor domains dictates the diffusion efficiency, which tends to be near unity. As a result, the BHJ active layer thickness may be increased to maximize light absorption.

To increase spectral coverage and further improve absorption, there are several alternative approaches to the above-referenced binary BHJ architecture (termed “binary” due to the use of a single donor and single acceptor in the active layer). A first approach includes a ternary or higher-order BHJ employing additional donor or acceptor molecules within the BHJ blend that can broaden the active layer absorption, assuming the added molecules are complementary absorbers. A second approach involves a planar-mixed heterojunction (PMHJ) employing additional donor or acceptor molecules as planar buffer layers adjacent to the BHJ blend to improve absorption. In some implementations, the photocurrent contribution from the planar layers is limited in a manner similar to the operation of standard planar heterojunctions.

A third approach includes a series tandem architecture, whereby a combination of planar heterojunctions, PMHJs, and/or BHJs of different compositions comprise individual subcells that are electrically connected through charge recombination zones. The charge recombination zones align the quasi-Fermi level for electrons in one subcell with that of the holes from another subcell, causing their output voltages to be additive. It should be noted that the photocurrent flowing through the series tandem may be limited by the lowest photocurrent subcell. Mechanically stacked tandem devices, utilizing a four terminal design can help alleviate this design criteria but require more electrode layers and engineering. Parallel tandem devices connect two or more subcells electrically in parallel in a three terminal device in which an interconnecting electrode serves as the common anode or cathode. In this way the currents of the subcell are additive but they are limited in voltage by the lowest voltage cell. These also have the added challenge of having an electrode buried between the two subcells.

Pertaining to transparent OPVs for architectural glass applications, active layers can be selected such that they have a relatively flat absorption within the visible spectrum. This can be important to achieving a neutral transmitted color of the overall device stack. For binary BHJs, two complementary absorbers may be used to span the entire visible spectrum at a specific composition. If the color-neutral composition is not the optimal composition for power production, this presents a tradeoff with the device's aesthetics. Introducing additional absorbers using the first approach can increase the number of compositions where color neutrality may be achieved, but this again may not coincide with maximal performance. The second approach has been successfully employed in devices to achieve color neutrality, whereby 14 nm of PTCBI was introduced as a color neutralizing layer. However, due to the short diffusion length of excitons in this film, the planar layer's absorption is effectively parasitic and minimally contributes to device performance. To maintain high average visible transmittance (AVT) in transparent OPVs while simultaneously maximizing power conversion efficiency (PCE), it can be important to use active layers that have a very high internal quantum efficiency. The third approach is generally implemented with the photocurrent from individual subcells being matched, which does not necessarily coincide with a color neutral device. Due to the lower photon flux at short wavelengths, often the blue-green absorbing subcells are thicker and more absorptive than the red-NIR subcells for current balance, which modifies the transmitted color.

Embodiments of the present invention provide for a stacked BHJ, where multiple BHJs are layered directly on top of one another to comprise the OPV active layers. The stacked BHJ architecture is extremely flexible and can replace or complement any of the three approaches described above.

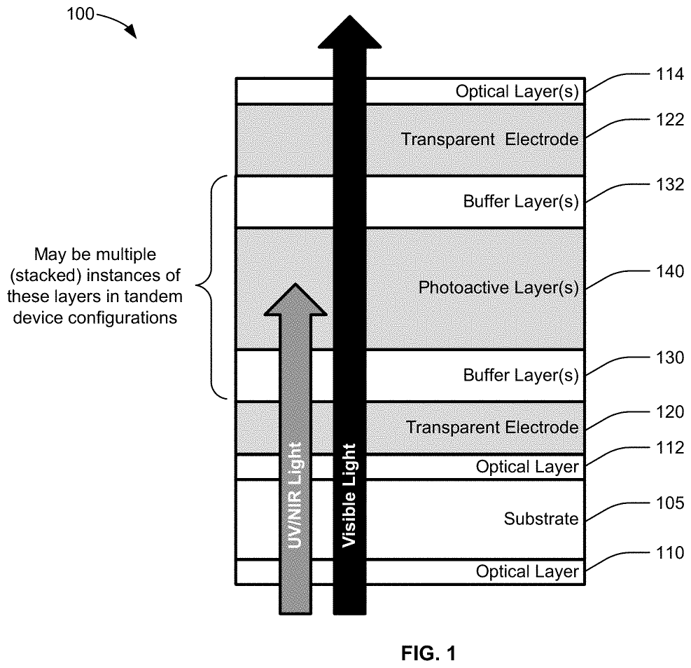

FIG. 1 illustrates a simplified schematic diagram of a visibly transparent photovoltaic device 100, according to an embodiment of the present invention. As illustrated in FIG. 1, visibly transparent photovoltaic device 100 includes a number of layers and elements discussed more fully below. As discussed herein, visibly transparent indicates that the photovoltaic device absorbs optical energy at wavelengths outside the visible wavelength band of 450 nm to 650 nm, for example, while substantially transmitting visible light inside the visible wavelength band. As illustrated in FIG. 1, UV and/or NIR light is absorbed in the layers and elements of the photovoltaic device while visible light is transmitted through the device. Thus, the discussion of transparency provided herein should be understood as visible transparency.

Substrate 105, which can be glass or other visibly transparent materials providing sufficient mechanical support to the other layers and structures illustrated, supports optical layers 110 and 112. These optical layers can provide a variety of optical properties, including antireflection (AR) properties, wavelength selective reflection or distributed Bragg reflection properties, index matching properties, encapsulation, or the like. Optical layers may advantageously be visibly transparent. An additional optical layer 114 can be utilized, for example, as an AR coating, an index matching later, a passive infrared or ultraviolet absorption layer, etc. Optionally, optical layers may be transparent to ultraviolet and/or near-infrared light or transparent to at least a subset of wavelengths in the ultraviolet and/or near-infrared bands. Depending on the configuration, additional optical layer 114 may also be a passive visible absorption layer. Example substrate materials include various glasses and rigid or flexible polymers. Multilayer substrates such as laminates and the like may also be utilized. Substrates may have any suitable thickness to provide the mechanical support needed for the other layers and structures, such as, for example, thicknesses from 1 mm to 20 mm. In some cases, the substrate may be or comprise an adhesive film to allow application of the visibly transparent photovoltaic device 100 to another structure, such as a window pane, display device, etc.

It will be appreciated that, although the devices overall may exhibit visible transparency, such as a transparency in the 450-650 nm range greater than 30%, greater than 40%, greater than 50%, greater than 60%, greater than 70%, or up to or approaching 100%, certain materials taken individually may exhibit absorption in portions of the visible spectrum. Optionally, each individual material or layer in a visibly transparent photovoltaic device has a high transparency in the visible range, such as greater than 30% (i.e., between 30% and 100%). It will be appreciated that transmission or absorption may be expressed as a percentage and may be dependent on the material's absorbance properties, a thickness or path length through an absorbing material, and a concentration of the absorbing material, such that a material with an absorbance in the visible spectral region may still exhibit a low absorption or high transmission if the path length through the absorbing material is short and/or the absorbing material is present in low concentration.

As described herein and below, photoactive materials in various photoactive layers advantageously exhibit minimal absorption in the visible region (e.g., less than 20%, less than 30%, less than 40%, less than 50%, less than 60%, or less than 70%), and instead exhibit high absorption in the near-infrared and/or ultraviolet regions (e.g., an absorption peak of greater than 50%, greater than 60%, greater than 70%, or greater than 80%). For some applications, absorption in the visible region may be as large as 70%. Various configurations of other materials, such as the substrate, optical layers, and buffer layers, may allow these materials to provide overall visible transparency, even though the materials may exhibit some amount of visible absorption. For example, a thin film of a metal may be included in a transparent electrode, such as a metal that exhibits visible absorption, like Ag or Cu; when provided in a thin film configuration, however, the overall transparency of the film may be high. Similarly, materials included in an optical or buffer layer may exhibit absorption in the visible range, but may be provided at a concentration or thickness where the overall amount of visible light absorption is low, providing visible transparency.

The visibly transparent photovoltaic device 100 also includes a set of transparent electrodes 120 and 122 with a photoactive layer 140 positioned between electrodes 120 and 122. These electrodes, which can be fabricated using ITO, thin metal films, or other suitable visibly transparent materials, provide electrical connection to one or more of the various layers illustrated. For example, thin films of copper, silver, or other metals may be suitable for use as a visibly transparent electrode, even though these metals may absorb light in the visible band. When provided as a thin film, however, such as a film having a thickness of 1 nm to 200 nm (e.g., about 5 nm, about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, about 105 nm, about 110 nm, about 115 nm, about 120 nm, about 125 nm, about 130 nm, about 135 nm, about 140 nm, about 145 nm, about 150 nm, about 155 nm, about 160 nm, about 165 nm, about 170 nm, about 175 nm, about 180 nm, about 185 nm, about 190 nm, or about 195 nm), an overall transmittance of the thin film in the visible band may remain high, such as greater than 30%, greater than 40%, greater than 50%, greater than 60%, greater than 70%, greater than 80%, or greater than 90%. Advantageously, thin metal films, when used as transparent electrodes, may exhibit lower absorption in the ultraviolet band than other semiconducting materials that may be useful as a transparent electrode, such as ITO, as some semiconducting transparent conducting oxides exhibit a band gap that occurs in the ultraviolet band and thus are highly absorbing or opaque to ultraviolet light. In some cases, however, an ultraviolet absorbing transparent electrode may be used, such as to screen at least a portion of the ultraviolet light from underlying components, as ultraviolet light may degrade certain materials.

A variety of deposition techniques may be used to generate a transparent electrode, including vacuum deposition techniques, such as atomic layer deposition, chemical vapor deposition, physical vapor deposition, thermal evaporation, sputter deposition, epitaxy, etc. Solution based deposition techniques, such as spin-coating, slot-die coating, blade coating, spray coating etc. may also be used in some cases. In addition, transparent electrodes may be patterned using techniques known in the art of microfabrication, including lithography, lift off, etching, etc.

Buffer layers 130 and 132 and photoactive layer 140 are utilized to implement the electrical and optical properties of the photovoltaic device. These layers can be layers of a single material or can include multiple sub-layers as appropriate to the particular application. Thus, the term “layer” is not intended to denote a single layer of a single material, but can include multiple sub-layers of the same or different materials. In some embodiments, buffer layer 130, photoactive layer(s) 140 and buffer layer 132 are repeated in a stacked configuration to provide tandem device configurations, such as including multiple heterojunctions. In some embodiments, the photoactive layer(s) include electron donor materials and electron acceptor materials, also referred to as donors and acceptors. These donors and acceptors are visibly transparent, but absorb outside the visible wavelength band to provide the photoactive properties of the device.

Useful buffer layers include those that function as electron transport layers, electron blocking layers, hole transport layers, hole blocking layers, exciton blocking layers, optical spacers, physical buffer layers, charge recombination layers, or charge generation layers. Buffer layers may exhibit any suitable thickness to provide the buffering effect desired and may optionally be present or absent. Useful buffer layers, when present, may have thicknesses from 1 nm to 1 μm. Various materials may be used as buffer layers, including fullerene materials, carbon nanotube materials, graphene materials, metal oxides, such as molybdenum oxide, titanium oxide, zinc oxide, etc., polymers, such as poly(3,4-ethylenedioxythiophene), polystyrene sulfonic acid, polyaniline, etc., copolymers, polymer mixtures, and small molecules, such as bathocuproine. Buffer layers may be applied using a deposition process (e.g., thermal evaporation) or a solution processing method (e.g., spin coating).

Examples of materials that can be utilized as active/buffer (transport layers)/optical materials in various embodiments of the present invention include near-IR absorbing materials, UV absorbing materials, and/or materials that are characterized by strong absorption peaks in the near-IR or UV regions of the electromagnetic spectrum. Near-IR absorbing materials include phthalocyanines, porphyrins, naphthalocyanines, squaraines, boron-dipyrromethenes, naphthalenes, rylenes, perylenes, tetracyano quinoidal thiophene compounds, tetracyano indacene compounds, carbazole thiaporphyrin compounds, metal dithiolates, benzothiadiazole containing compounds, dicyanomethylene indanone containing compounds, combinations thereof, and the like. UV absorbing materials include fullerenes, rylenes, perylenes, benzimidazoles, hexacarbonitriles, triarylamines, bistriarylamines, phenanthrolines, para-phenylenes, combinations thereof and the like.

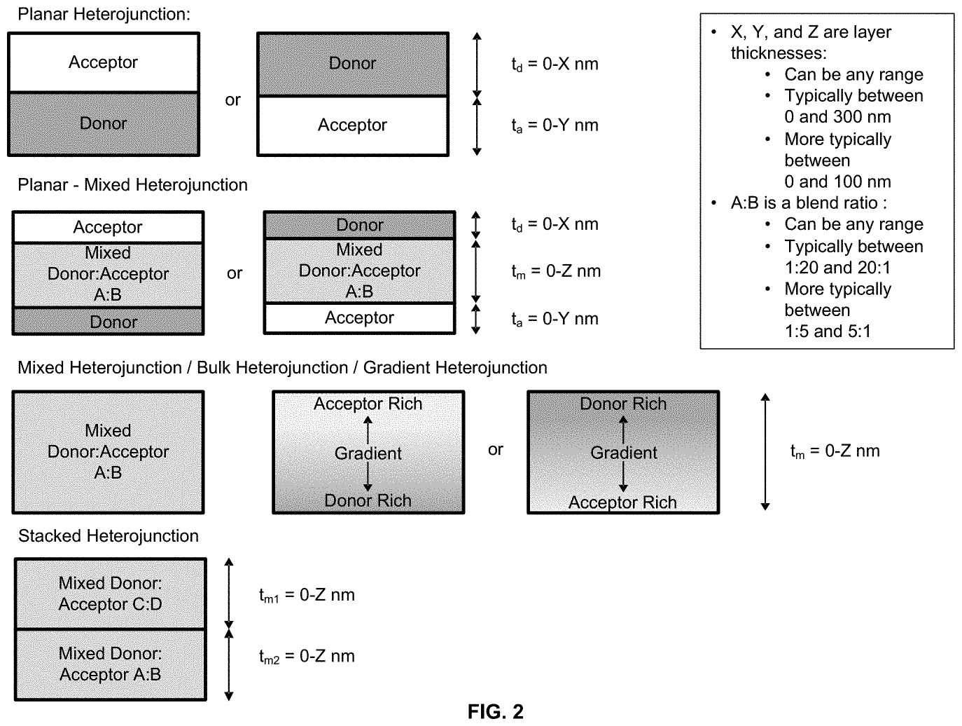

FIG. 2 illustrates an overview of various example junction configurations for photoactive layer 140. Photoactive layer 140 may optionally correspond to mixed donor/acceptor (bulk heterojunction) configurations, planar donor/acceptor configurations, planar and mixed donor/acceptor configurations, gradient donor/acceptor configurations, or stacked heterojunction configurations. Various materials may optionally be used as the photoactive layers 140, such as materials that absorb in the ultraviolet band or the near-infrared band but that only absorb minimally, if at all, in the visible band. In this way, the photoactive material may be used to generate electron-hole pairs for powering an external circuit by way of ultraviolet and/or near-infrared absorption, leaving the visible light relatively unperturbed to provide visible transparency. As illustrated, photoactive layer 140 may comprise a planar heterojunction including separate donor and acceptor layers. Photoactive layer 140 may alternatively comprise a planar-mixed heterojunction structure including separate acceptor and donor layers and a mixed donor-acceptor layer. Photoactive layer 140 may alternatively comprise a mixed heterojunction structure including a fully mixed acceptor-donor layer or those including a mixed donor-acceptor layer with various relative concentration gradients.

Photoactive layers may have any suitable thickness and may have any suitable concentration or composition of photoactive materials to provide a desired level of transparency and ultraviolet/near-infrared absorption characteristics. Example thicknesses of a photoactive layer may range from about 1 nm to about 1 μm, about 1 nm to about 300 nm, or about 1 nm to about 100 nm. In some cases, photoactive layers may be made up of individual sub-layers or mixtures of layers to provide suitable photovoltaic power generation characteristics, as illustrated in FIG. 2. The various configurations depicted in FIG. 2 may be used and dependent on the particular donor and acceptor materials used in order to provide advantageous photovoltaic power generation. For example, some donor and acceptor combinations may benefit from particular configurations, while other donor and acceptor combinations may benefit from other particular configurations. Donor materials and acceptor materials may be provided in any ratio or concentration to provide suitable photovoltaic power generation characteristics. For mixed layers, the relative concentration of donors to acceptors is optionally between about 20 to 1 and about 1 to 20. Optionally, the relative concentration of donors to acceptors is optionally between about 5 to 1 and about 1 to 5. Optionally, donors and acceptors are present in a 1 to 1 ratio.

Various visibly transparent photoactive compounds are useful as an electron donor photoactive material and, in some embodiments, may be paired with suitable electron acceptor photoactive materials in order to provide a useful photoactive layer in the photovoltaic device.

Various visibly transparent photoactive compounds are useful as an electron acceptor photoactive material, and may be paired with suitable electron donor photoactive materials in order to provide a useful photoactive layer in the photovoltaic device. Example donor and acceptor materials are described in U.S. Provisional Application Nos. 62/521,154, 62/521,158, 62/521,160, 62/521,211, 62/521,214, and 62/521,224, each filed on Jun. 16, 2017, which are hereby incorporated by reference in their entireties.

In embodiments, the chemical structure of various photoactive compounds can be functionalized with one or more directing groups, such as electron donating groups, electron withdrawing groups, or substitutions about or to a core metal atom, in order to provide desirable electrical characteristics to the material. For example, in some embodiments, the photoactive compounds are functionalized with amine groups, phenol groups, alkyl groups, phenyl groups, or other electron donating groups to improve the ability of the material to function as an electron donor in a photovoltaic device. As another example, in some embodiments, the photoactive compounds are functionalized with cyano groups, halogens, sulfonyl groups, or other electron withdrawing groups to improve the ability of the material to function as an electron acceptor in a photovoltaic device.

In embodiments, the photoactive compounds are functionalized to provide desirable optical characteristics. For example, in some embodiments, the photoactive compounds may be functionalized with an extended conjugation to redshift the absorption profile of the material. It will be appreciated that conjugation may refer to a delocalization of pi electrons in a molecule and may be characterized by alternating single and multiple bonds in a molecular structure. For example, functionalizations that extend the electron conjugation may include fusing one or more aromatic groups to the molecular structure of the material. Other functionalizations that may provide extended conjugation include alkene functionalization, such as by a vinyl group, aromatic or heteroaromatic functionalization, carbonyl functionalization, such as by an acyl group, sulfonyl functionalization, nitro functionalization, cyano functionalization, etc. It will be appreciated that various molecular functionalizations may impact both the optical and the electrical properties of the photoactive compounds.

It will be appreciated that device function may be impacted by the morphology of the active layers in the solid state. Separation of electron donors and acceptors into discrete domains, with dimensions on the scale of the exciton diffusion length and large interfacial areas, can be advantageous for achieving high device efficiency. Advantageously, the molecular framework of the photoactive materials can be tailored to control the morphology of the materials. For example, the introduction of functional groups as described herein can have large impacts to the morphology of the material in the solid state, regardless of whether such modifications impact the energetics or electronic properties of the material. Such morphological variations can be observed in pure materials and when a particular material is blended with a corresponding donor or acceptor. Useful functionalities to control morphology include, but are not limited to, addition of alkyl chains, conjugated linkers, fluorinated alkanes, bulky groups (e.g., tert-butyl, phenyl, naphthyl or cyclohexyl), as well as more complex coupling procedures designed to force parts of the structure out of the plane of the molecule to inhibit excessive crystallization.

In embodiments, other molecular structural characteristics may provide desirable electrical and optical properties in the photoactive compounds. For example, in some embodiments, the photoactive compounds may exhibit portions of the molecule that may be characterized as electron donating while other portions of the molecule may be characterized as electron accepting. Without wishing to be bound by any theory, molecules including alternating electron donating and electron accepting portions may result in redshifting the absorption characteristics of the molecule as compared to similar molecules lacking alternating electron donating and electron accepting portions. For example, alternating electron donating and electron accepting portions may decrease or otherwise result in a lower energy gap between a highest occupied molecular orbital and a lowest unoccupied molecular orbital. Organic donor and/or acceptor groups may be useful as R-group substituents, such as on any aryl, aromatic, heteroaryl, heteroaromatic, alkyl, or alkenyl group, in the visibly transparent photoactive compounds.

When the donor/acceptor materials are incorporated as a photoactive layer in a transparent photovoltaic device as either an electron donor or electron acceptor, the layer thicknesses can be controlled to vary device output, absorbance, or transmittance. For example, increasing the donor or acceptor layer thickness can increase the light absorption in that layer. In some cases, increasing a concentration of donor/acceptor materials in a donor or acceptor layer may similarly increase the light absorption in that layer. However, in some embodiments, a concentration of donor/acceptor materials may not be adjustable, such as when active material layers comprise pure or substantially pure layers of donor/acceptor materials or pure or substantially pure mixtures of donor/acceptor materials. Optionally, donor/acceptor materials may be provided in a solvent or suspended in a carrier, such as a buffer layer material, in which case the concentration of donor/acceptor materials may be adjusted. In some embodiments, the donor layer concentration is selected where the current produced is maximized. In some embodiments, the acceptor layer concentration is selected where the current produced is maximized.

However, the charge collection efficiency can decrease with increasing donor or acceptor thickness due to the increased “travel distance” for the charge carriers. Therefore, there may be a trade-off between increased absorption and decreasing charge collection efficiency with increasing layer thickness. It can thus be advantageous to select materials that have a high absorption coefficient and/or concentration to allow for increased light absorption per thickness. In some embodiments, the donor layer thickness is selected where the current produced is maximized. In some embodiments, the acceptor layer thickness is selected where the current produced is maximized.

In addition to the individual photoactive layer thicknesses, the thickness and composition of the other layers in the transparent photovoltaic device can also be selected to enhance absorption within the photoactive layers. The other layers (buffer layers, electrodes, etc.), are typically selected based on their optical properties (index of refraction and extinction coefficient) in the context of the thin film device stack and resulting optical cavity. For example, a near-infrared absorbing photoactive layer can be positioned in the peak of the optical field for the near-infrared wavelengths where it absorbs to maximize absorption and resulting current produced by the device. This can be accomplished by spacing the photoactive layer at an appropriate distance from the electrode using a second photoactive layer and/or optical layers as spacer. A similar scheme can be used for ultraviolet absorbing photoactive layers. In many cases, the peaks of the longer wavelength optical fields will be positioned further from the more reflective of the two transparent electrodes compared to the peaks of the shorter wavelength optical fields. Thus, when using separate donor and acceptor photoactive layers, the donor and acceptor can be selected to position the more red absorbing (longer wavelength) material further from the more reflective electrode and the more blue absorbing (shorter wavelength) closer to the more reflective electrode.

In some embodiments, optical layers may be included to increase the intensity of the optical field at wavelengths where the donor absorbs in the donor layer to increase light absorption and hence, increase the current produced by the donor layer. In some embodiments, optical layers may be included to increase the intensity of the optical field at wavelengths where the acceptor absorbs in the acceptor layer to increase light absorption and hence, increase the current produced by the acceptor layer. In some embodiments, optical layers may be used to improve the transparency of the stack by either decreasing visible absorption or visible reflection. Further, the electrode material and thickness may be selected to enhance absorption outside the visible range within the photoactive layers, while preferentially transmitting light within the visible range.

Optionally, enhancing spectral coverage of a visibly transparent photovoltaic device is achieved by the use of a multi-cell series stack of visibly transparent photovoltaic devices, referred to as tandem cells, which may be included as multiple stacked instances of buffer layer 130, photoactive layer 140, and buffer layer 132, as described with reference to FIG. 1. This architecture includes more than one photoactive layer, which are typically separated by a combination of buffer layer(s) and/or thin metal layers, for example. In this architecture, the currents generated in each subcell flow in series to the opposing electrodes and therefore, the net current in the cell is limited by the smallest current generated by a particular subcell, for example. The open circuit voltage (VOC) is equal to the sum of the VOCs of the subcells. By combining sub-cells fabricated with different donor-acceptors pairs which absorb in different regions of the solar spectrum, a significant improvement in efficiency relative to a single junction cell can be achieved.

Additional description related to the materials utilized in one or more of the buffer layers and the photoactive layers, including donor layers and/or acceptor layers, are provided below.

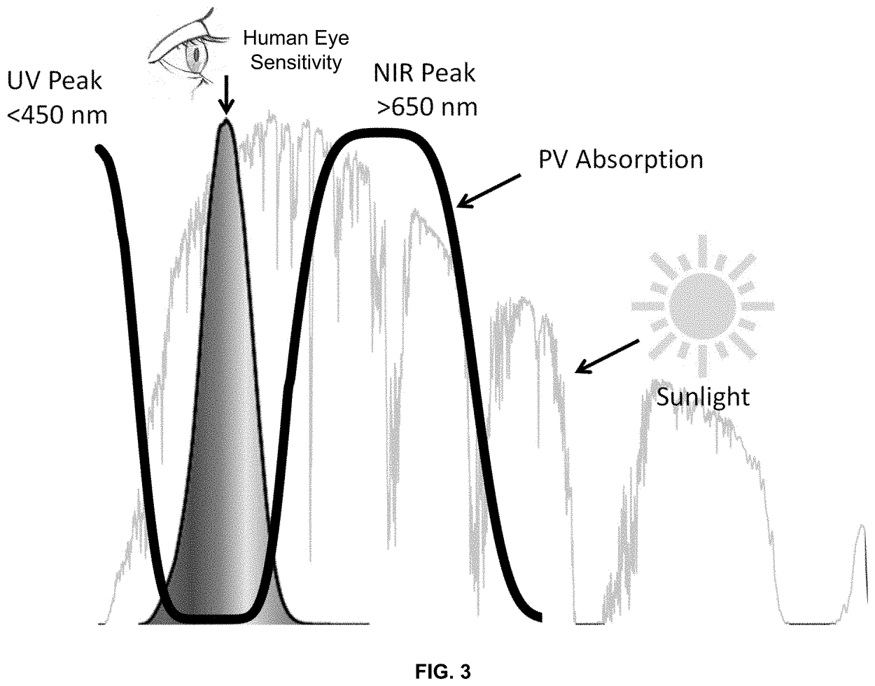

FIG. 3 illustrates a simplified plot of the solar spectrum, human eye sensitivity, and exemplary visibly transparent photovoltaic device absorption as a function of wavelength. As illustrated in FIG. 3, embodiments of the present invention utilize photovoltaic structures that have low absorption in the visible wavelength band between about 450 nm and about 650 nm, but absorb in the UV and NIR bands, i.e., outside the visible wavelength band, enabling visibly transparent photovoltaic operation. The ultraviolet band or ultraviolet region may be described, in embodiments, as wavelengths of light of between about 200 nm and 450 nm. It will be appreciated that useful solar radiation at ground level may have limited amounts of ultraviolet less than about 280 nm and, thus, the ultraviolet band or ultraviolet region may be described as wavelengths of light of between about 280 nm and 450 nm, in some embodiments. The near-infrared band or near-infrared region may be described, in embodiments, as wavelengths of light of between about 650 nm and 1400 nm. Various compositions described herein may exhibit absorption including a UV peak and/or a NIR peak with a maximum absorption strength in the visible region that is smaller than that in the NIR region or UV region.

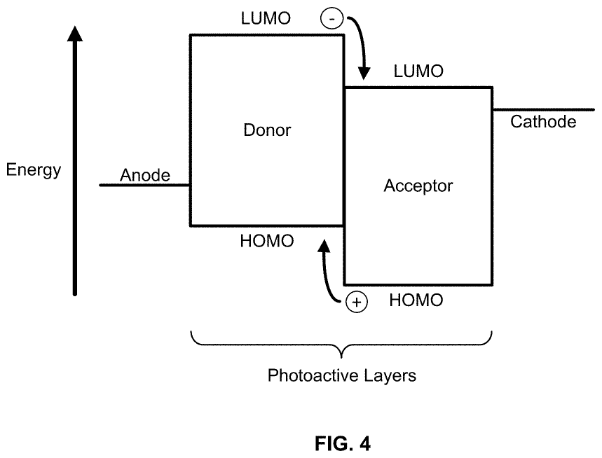

FIG. 4 illustrates a schematic energy level diagram overview for operation of an example organic photovoltaic device, such as visibly transparent photovoltaic device 100. For example, in such a photovoltaic device, various photoactive materials may exhibit electron donor or electron acceptor characteristics, depending on their molecular properties and the types of materials that are used for buffer layers, electrodes, etc. As depicted in FIG. 4, each of the donor and acceptor materials have a HOMO and a LUMO. A transition of an electron from the HOMO to the LUMO may be imparted by absorption of photons. The energy between the HOMO and the LUMO (the HOMO-LUMO gap) of a material represents approximately the energy of the optical band gap of the material. For the electron donor and electron acceptor materials useful with the transparent photovoltaic devices provided herein, the HOMO-LUMO gap for the electron donor and electron acceptor materials may optionally fall outside the energy of photons in the visible range. For example, the HOMO-LUMO gap may be in the ultraviolet region or the near-infrared region, depending on the photoactive materials. It will be appreciated that the HOMO is comparable to the valence band in conventional conductors or semiconductors, while the LUMO is comparable to the conduction band in conventional conductors or semiconductors.

The buffer layer adjacent to the donor, generally referred to as the anode buffer layer or hole transport layer, is selected such that HOMO level or valence band (in the case of inorganic materials) of the buffer layer is aligned in the energy landscape with the HOMO level of the donor to transport holes from the donor to the anode (transparent electrode). In some embodiments, it may be useful for the buffer layer to have high hole mobility. The buffer layer adjacent to the acceptor, generally referred to as the cathode buffer layer or electron transport layer, is selected such that LUMO level or conduction band (in the case of inorganic materials) of the buffer layer is aligned in the energy landscape with the LUMO level of the acceptor to transport electrons from the acceptor to the cathode (transparent electrode). In some embodiments, it may be useful for the buffer layer to have high electron mobility.

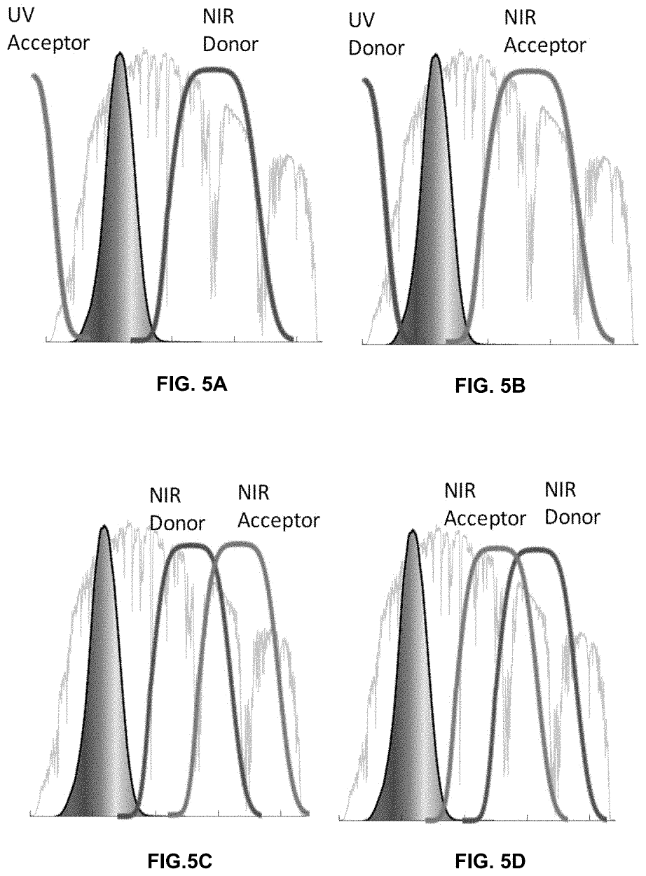

FIGS. 5A-5D illustrate various plots showing example absorption bands for different electron donor and electron acceptor configurations useful with visibly transparent photovoltaic devices. In FIG. 5A, the donor material exhibits absorption in the NIR, while the acceptor material exhibits absorption in the UV. FIG. 5B depicts the opposite configuration, where the donor material exhibits absorption in the UV, while the acceptor material exhibits absorption in the NIR.

FIG. 5C depicts an additional configuration, where both the donor and acceptor materials exhibit absorption in the NIR. As illustrated in the figures, the solar spectrum exhibits significant amounts of useful radiation in the NIR with only relatively minor amounts in the ultraviolet, making the configuration depicted in FIG. 5C useful for capturing a large amount of energy from the solar spectrum. It will be appreciated that other embodiments are contemplated where both the donor and acceptor materials exhibit absorption in the NIR, such as depicted in FIG. 5D where the acceptor is blue shifted relative to the donor, opposite the configuration depicted in FIG. 5C, where the donor is blue shifted relative to the acceptor.

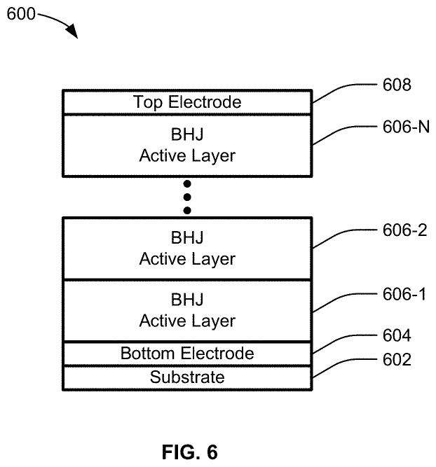

FIG. 6 illustrates a device structure 600, according to an embodiment of the present invention. Device structure 600 comprises multiple “stacked” BHJ active layers 606 between a top electrode 608 and a bottom electrode 604, which may be formed on a substrate 602. Each of the active layers are layered directly on top of one another such that the BHJ active layers add their photocurrents to the overall output of the photovoltaic cell. The BHJ active layers may thus be considered to be in contact with each other.

Unlike a series tandem arrangement, there are no charge recombination zones between the BHJ active layers. As a result, the photocurrents are additive between BHJ active layers 606. By incorporating at least one unique active layer material into each of BHJ active layers 606, the absorption of device structure 600 can be tailored for a desired spectral coverage.

In the case of binary blends, BHJ active layers 606 retain their processing control while affording the spectral coverage of a ternary or a higher order BHJ. Optically, the stacked BHJ may be superior to a ternary BHJ since each specific donor or acceptor molecule may be spatially positioned at the optical field peak corresponding to its peak absorption wavelength. For a ternary (or higher order) BHJ, the constituent molecules are blended throughout the stack, even at locations where their absorption is less. The stacked BHJ is also compatible with ternary or higher order blends within the BHJ layers.

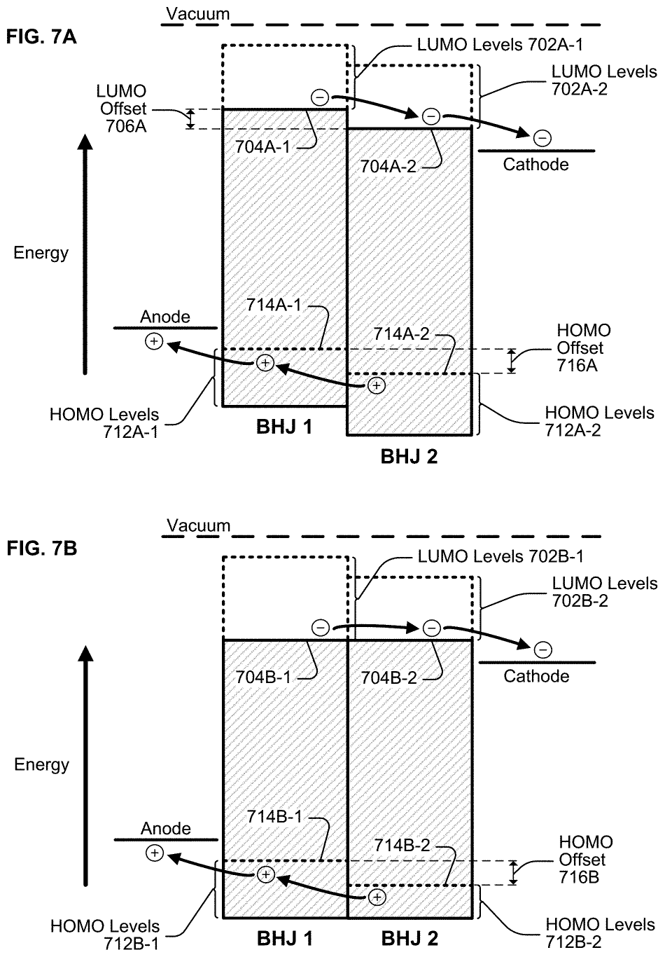

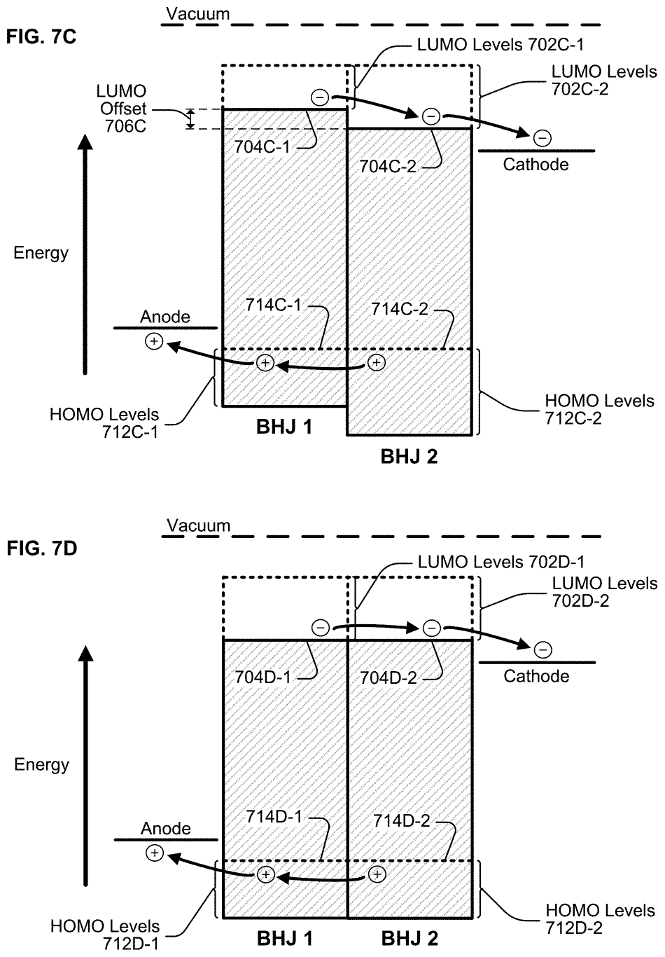

FIGS. 7A-7D illustrate energy level diagrams schematically showing a stacked BHJ containing two BHJ layers with dissimilar electron donor and acceptor materials (FIG. 7A), dissimilar electron donor and shared acceptor materials (FIG. 7B), shared donor and dissimilar acceptor materials (FIG. 7C), and shared donor and acceptor materials (FIG. 7D). In FIGS. 7A-7D, dashed lines may correspond to the electron donor materials and the shaded regions enclosed by solid lines may correspond to the electron acceptor materials. Material combinations can be selected such that their HOMO or LUMO energy level offsets decrease in energy towards the anode or cathode, respectively.

In reference to FIG. 7A, an energy level diagram is illustrated for a stacked BHJ containing two BHJ layers (“BHJ 1” and “BHJ 2”). In the example illustrated in FIG. 7A, the electron donor material used in BHJ 1 is different than the electron donor material used in BHJ 2, and the electron acceptor material used in BHJ 1 is different than the electron acceptor material used in BHJ 2.

In the illustrated example, BHJ 1 includes a set of LUMO energy levels 702A-1 (e.g., including the LUMO energy level of the electron acceptor material used in BHJ 1 and the LUMO energy level of the electron donor material used in BHJ 1) and an overall LUMO energy level 704A-1, which may correspond to the minimum energy level of the set of LUMO energy levels 702A-1. BHJ 2 includes a set of LUMO energy levels 702A-2 (e.g., including the LUMO energy level of the electron acceptor material used in BHJ 2 and the LUMO energy level of the electron donor material used in BHJ 2) and an overall LUMO energy level 704A-2, which may correspond to the minimum energy level of the set of LUMO energy levels 702A-2. The difference between LUMO energy levels 704A-1 and 704A-2 is equal to a LUMO energy level offset 706A. Materials used in BHJ 1 and BHJ 2 may be selected such that LUMO energy level offset 706A is positive (i.e., LUMO energy level 704A-1 is greater than LUMO energy level 704A-2) and such that electrons excited to the LUMO of BHJ 1 experience energetically favorable travel through BHJ 2 to the cathode.

BHJ 1 includes a set of HOMO energy levels 712A-1 (e.g., including the HOMO energy level of the electron acceptor material used in BHJ 1 and the HOMO energy level of the electron donor material used in BHJ 1) and an overall HOMO energy level 714A-1, which may correspond to the maximum energy level of the set of HOMO energy levels 712A-1. BHJ 2 includes a set of HOMO energy levels 712A-2 (e.g., including the HOMO energy level of the electron acceptor material used in BHJ 2 and the HOMO energy level of the electron donor material used in BHJ 2) and an overall HOMO energy level 714A-2, which may correspond to the maximum energy level of the set of HOMO energy levels 712A-2. The difference between HOMO energy levels 714A-1 and 714A-2 is equal to a HOMO energy level offset 716A. Materials used in BHJ 1 and BHJ 2 may be selected such that HOMO energy level offset 716A is positive (i.e., HOMO energy level 714A-1 is greater than HOMO energy level 714A-2) and such holes in BHJ 2 experience energetically favorable travel through BHJ 1 to the anode.

In reference to FIG. 7B, an energy level diagram is illustrated for a stacked BHJ containing two BHJ layers (“BHJ 1” and “BHJ 2”). In the example illustrated in FIG. 7B, the electron donor material used in BHJ 1 is different than the electron donor material used in BHJ 2, and the electron acceptor material used in BHJ 1 is the same as (and/or energetically similar to) the electron acceptor material used in BHJ 2.

In the illustrated example, BHJ 1 includes a set of LUMO energy levels 702B-1 (e.g., including the LUMO energy level of the electron acceptor material used in BHJ 1 and the LUMO energy level of the electron donor material used in BHJ 1) and an overall LUMO energy level 704B-1, which may correspond to the minimum energy level of the set of LUMO energy levels 702B-1. BHJ 2 includes a set of LUMO energy levels 702B-2 (e.g., including the LUMO energy level of the electron acceptor material used in BHJ 2 and the LUMO energy level of the electron donor material used in BHJ 2) and an overall LUMO energy level 704B-2, which may correspond to the minimum energy level of the set of LUMO energy levels 702B-2. Because the electron acceptor materials are the same, there is no LUMO energy level offset between BHJ 1 and BHJ 2, and electrons excited to the LUMO of BHJ 1 may travel through BHJ 2 to the cathode.

BHJ 1 includes a set of HOMO energy levels 712B-1 (e.g., including the HOMO energy level of the electron acceptor material used in BHJ 1 and the HOMO energy level of the electron donor material used in BHJ 1) and an overall HOMO energy level 714B-1, which may correspond to the maximum energy level of the set of HOMO energy levels 712B-1. BHJ 2 includes a set of HOMO energy levels 712B-2 (e.g., including the HOMO energy level of the electron acceptor material used in BHJ 2 and the HOMO energy level of the electron donor material used in BHJ 2) and an overall HOMO energy level 714B-2, which may correspond to the maximum energy level of the set of HOMO energy levels 712B-2. The difference between HOMO energy levels 714B-1 and 714B-2 is equal to a HOMO energy level offset 716B.

Materials used in BHJ 1 and BHJ 2 may be selected such that HOMO energy level offset 716B is positive (i.e., HOMO energy level 714B-1 is greater than HOMO energy level 714B-2) and holes in BHJ 2 experience energetically favorable travel through BHJ 1 to the anode.

In reference to FIG. 7C, an energy level diagram is illustrated for a stacked BHJ containing two BHJ layers (“BHJ 1” and “BHJ 2”). In the example illustrated in FIG. 7C, the electron donor material used in BHJ 1 is the same as (and/or similar to) the electron donor material used in BHJ 2, and the electron acceptor material used in BHJ 1 is different than the electron acceptor material used in BHJ 2.

In the illustrated example, BHJ 1 includes a set of LUMO energy levels 702C-1 (e.g., including the LUMO energy level of the electron acceptor material used in BHJ 1 and the LUMO energy level of the electron donor material used in BHJ 1) and an overall LUMO energy level 704C-1, which may correspond to the minimum energy level of the set of LUMO energy levels 702C-1. BHJ 2 includes a set of LUMO energy levels 702C-2 (e.g., including the LUMO energy level of the electron acceptor material used in BHJ 2 and the LUMO energy level of the electron donor material used in BHJ 2) and an overall LUMO energy level 704C-2, which may correspond to the minimum energy level of the set of LUMO energy levels 702C-2. The difference between LUMO energy levels 704C-1 and 704C-2 is equal to a LUMO energy level offset 706C. Materials used in BHJ 1 and BHJ 2 may be selected such that LUMO energy level offset 706C is positive (i.e., LUMO energy level 704C-1 is greater than LUMO energy level 704C-2), thereby causing electrons excited to the LUMO of BHJ 1 to travel through BHJ 2 to the cathode.

BHJ 1 includes a set of HOMO energy levels 712C-1 (e.g., including the HOMO energy level of the electron acceptor material used in BHJ 1 and the HOMO energy level of the electron donor material used in BHJ 1) and an overall HOMO energy level 714C-1, which may correspond to the maximum energy level of the set of HOMO energy levels 712C-1. BHJ 2 includes a set of HOMO energy levels 712C-2 (e.g., including the HOMO energy level of the electron acceptor material used in BHJ 2 and the HOMO energy level of the electron donor material used in BHJ 2) and an overall HOMO energy level 714C-2, which may correspond to the maximum energy level of the set of HOMO energy levels 712C-2. Because the electron donor materials are the same, there is no HOMO energy level offset between BHJ 1 and BHJ 2, thereby causing holes in BHJ 2 to travel through BHJ 1 to the anode.

In reference to FIG. 7D, an energy level diagram is illustrated for a stacked BHJ containing two BHJ layers (“BHJ 1” and “BHJ 2”). In the example illustrated in FIG. 7D, the electron donor material used in BHJ 1 is the same as (and/or energetically similar to) the electron donor material used in BHJ 2, and the electron acceptor material used in BHJ 1 is the same as (and/or similar to) the electron acceptor material used in BHJ 2 (at least one donor or acceptor varies between the layers).

In the illustrated example, BHJ 1 includes a set of LUMO energy levels 702D-1 (e.g., including the LUMO energy level of the electron acceptor material used in BHJ 1 and the LUMO energy level of the electron donor material used in BHJ 1) and an overall LUMO energy level 704D-1, which may correspond to the minimum energy level of the set of LUMO energy levels 702D-1. BHJ 2 includes a set of LUMO energy levels 702D-2 (e.g., including the LUMO energy level of the electron acceptor material used in BHJ 2 and the LUMO energy level of the electron donor material used in BHJ 2) and an overall LUMO energy level 704D-2, which may correspond to the minimum energy level of the set of LUMO energy levels 702D-2. Because the electron acceptor materials are the same, there is no LUMO energy level offset between BHJ 1 and BHJ 2, thereby causing electrons excited to the LUMO of BHJ 1 to travel through BHJ 2 to the cathode.

BHJ 1 includes a set of HOMO energy levels 712D-1 (e.g., including the HOMO energy level of the electron acceptor material used in BHJ 1 and the HOMO energy level of the electron donor material used in BHJ 1) and an overall HOMO energy level 714D-1, which may correspond to the maximum energy level of the set of HOMO energy levels 712D-1. BHJ 2 includes a set of HOMO energy levels 712D-2 (e.g., including the HOMO energy level of the electron acceptor material used in BHJ 2 and the HOMO energy level of the electron donor material used in BHJ 2) and an overall HOMO energy level 714D-2, which may correspond to the maximum energy level of the set of HOMO energy levels 712D-2. Because the electron donor materials are the same, there is no HOMO energy level offset between BHJ 1 and BHJ 2, thereby causing holes in BHJ 2 to travel through BHJ 1 to the anode.

In some embodiments, the electron donor material used in BHJ 1 is different than the electron donor material used in BHJ 2 and the electron acceptor material used in BHJ 1 is different than the electron acceptor material used in BHJ 2. In such embodiments, the electron donor material used in BHJ 1 may have aligned energy levels with the electron donor material used in BHJ 2 and the electron acceptor material used in BHJ 1 may have aligned energy levels with the electron acceptor material used in BHJ 2.

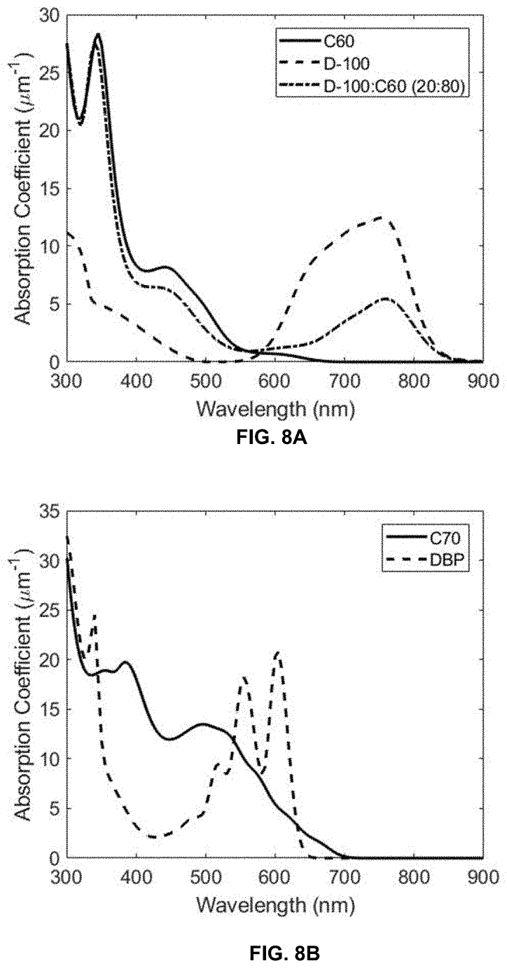

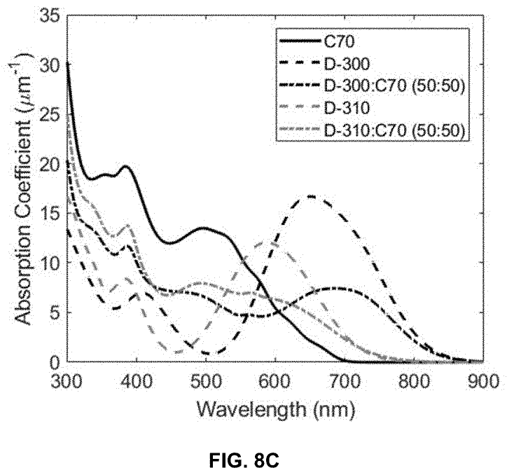

FIGS. 8A-8C illustrated absorption coefficients for exemplary active layer materials that can be utilized in various embodiments of the present invention. As illustrated in FIGS. 8A-8C, the active layer materials can be characterized by strong absorption peaks in the UV, the near-IR, or both regions of the spectrum. In particular, depending on the particular materials utilized for the active layer, the strength and the spectral width of the absorption coefficient can vary, enabling control of system performance. Furthermore, combinations of multiple materials can be utilized to tailor the peak amplitude and spectral width of the absorption coefficient. One of ordinary skill in the art would recognize many variations, modifications, and alternatives.

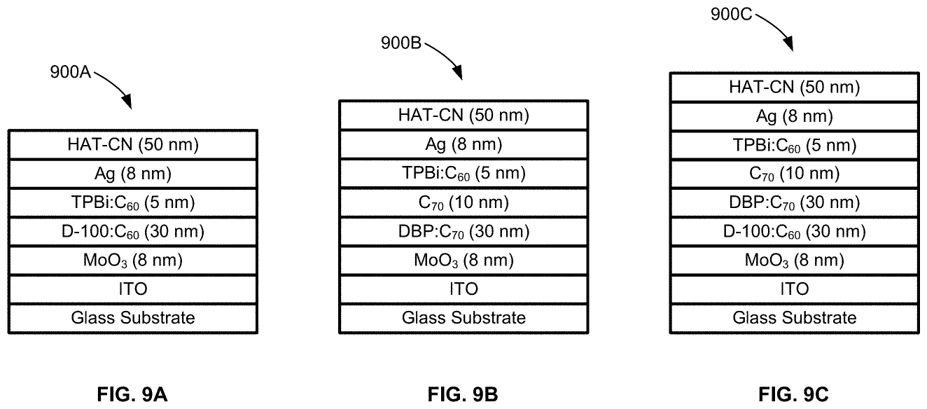

FIGS. 9A-9C illustrate various device structures, including a device structure 900A for a NIR-absorbing BHJ (FIG. 9A), a device structure 900B for a visibly absorbing planar-mixed heterojunction (FIG. 9B), and a device structure 900C for a stacked BHJ based on device structures 900A and 900B with a spectral response from UV-NIR. The D-100:C₆₀ and DBP:C₇₀ blends constitute two different electron donor materials and two different electron acceptor materials. The ITO layer may correspond to the anode. The MoO₃ layer may function as a hole injection layer and may be considered part of the anode structure or as a buffer layer coupled to the anode. The Ag layer may correspond to the cathode. The TPBi:C₆₀ layer may be considered part of the cathode structure or as a buffer layer coupled to the cathode. The HAT-CN layer may correspond to an optical layer or as an encapsulating layer to the cathode. In some examples, the D-100:C₆₀ and DBP:C₇₀ blends are maintained at a donor to acceptor ratio of 20:80 and 14:86 by volume, respectively. This represents a structure with dissimilar electron donors and acceptors in each BHJ layer. In FIG. 9C, the D-100:C₆₀ layer and the DBP:C₇₀ layer are placed on top of each other and are complementary absorbers. Although a particular exemplary donor (or acceptor) is illustrated in FIG. 9, embodiments of the present invention are not limited to a particular example and other donors and/or acceptors can be utilized according to various embodiments of the present invention. One of ordinary skill in the art would recognize many variations, modifications, and alternatives.

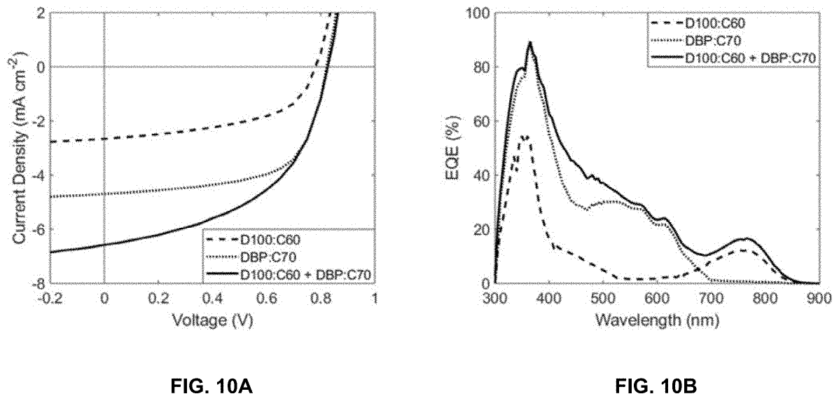

FIGS. 10A and 10B illustrate current density-voltage (FIG. 10A) and external quantum efficiency (EQE) curves (FIG. 10B) for the device structures shown in FIGS. 9A-9C. Specifically, the dashed lines correspond to device structure 900A, the dotted lines correspond to device structure 900B, and the solid lines correspond to device structure 900C. As can be seen, the photocurrent is additive between the two constituent devices resulting in an increased power output from the stacked BHJ. The EQE curve of the stacked BHJ shows efficient photocurrent generation from both BHJ layers within the stack, whose spectral response cumulatively extends from the UV to NIR. The EQE curve for DBP:C₇₀ is complementary to the EQE curve for D-100:C₆₀ by filling in between the two peaks of the D-100:C₆₀ curve.

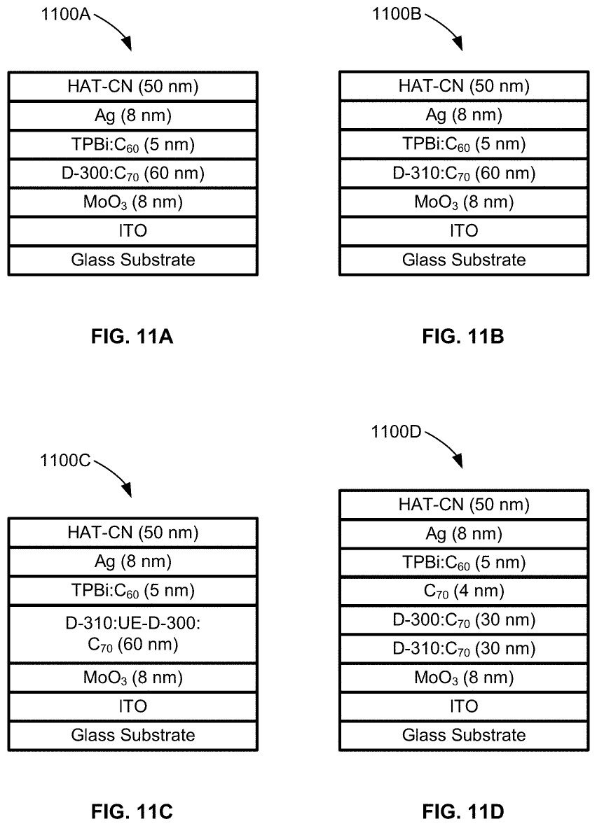

FIGS. 11A-11D illustrate various device structures, including device structures 1100A and 1100B for two binary BHJ devices (FIGS. 11A and 11B, respectively) employing dissimilar electron donors (D-300 and D-310, respectively) and an identical electron acceptor (C₇₀), a device structure 1100C having a ternary blend employing both donors (FIG. 11C), and a device structure 1100D having a corresponding stacked BHJ (FIG. 11D). The ITO layers, the MoO₃ layers, the Ag layers, and the TPBi:C₆₀ layers constitute electrode and buffer layers as described above. In each BHJ layer, the donor to acceptor ratio is maintained at 50:50 by volume, and in the ternary blend the overall composition is D310:D300:C₇₀ (25:25:50) by volume. In some examples, the donor content is identical between the ternary BHJ and stacked BHJ structures, but spatially segregated in the stacked BHJ case. The total active layer thickness can be maintained at 60 nm in all cases. In other embodiments, other total active layer thicknesses are utilized, including differing total active layer thicknesses. Although particular exemplary donors and combinations of donors are illustrated in FIGS. 11A-11D, embodiments of the present invention are not limited to a particular example and other donors and/or combinations of donors can be utilized according to various embodiments of the present invention. Similarly, the present invention is not limited to the exemplary acceptors illustrated in the present figures and other acceptors and combinations of acceptors are included within the scope of the present invention. One of ordinary skill in the art would recognize many variations, modifications, and alternatives.

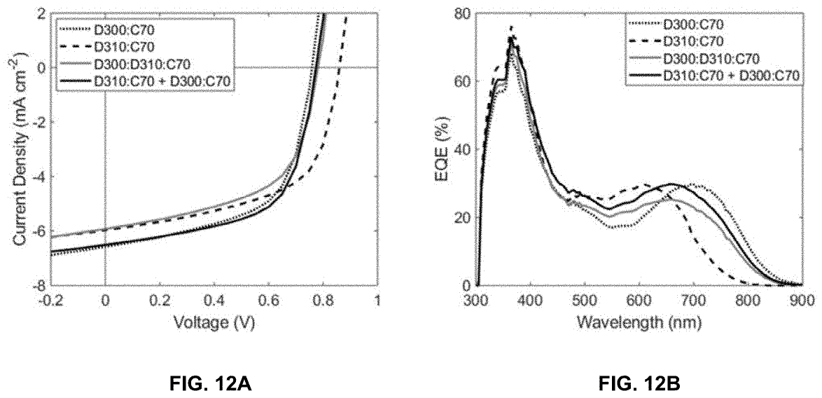

FIGS. 12A and 12B illustrate current density-voltage (FIG. 12A) and EQE curves (FIG. 12B) for the device structures shown in FIGS. 11A-11D. Specifically, the dotted lines correspond to device structure 1100A, the dashed lines correspond to device structure 1100B, the gray solid lines correspond to device structure 1100C, and the black solid lines correspond to device structure 1100D. As can be seen, the output voltage from both the ternary BHJ and stacked BHJ is limited by the lowest voltage material. The resulting EQE spectra appear as an average of the two binary BHJs, however the photocurrent output and EQE response is higher for the stacked BHJ than the ternary BHJ. FIGS. 12A and 12B demonstrate the advantages of employing a stacked BHJ rather than a ternary blend by obtaining higher photocurrents and EQE values, resulting in a higher efficiency.

Furthermore, the stacked BHJ can be tuned so that the EQE peak can be placed anywhere between the EQE peaks for the constituent BHJ layers. Tuning of the stacked BHJ can be performed by varying the composition and/or thickness of the constituent blends. For example, the composition of D310:C70 can vary between, for example, a volume ratio of 1:99 to 99:1, the composition of D300:C₇₀ can vary between, for example, a volume ratio of 1:99 to 99:1, and the thicknesses of D310:C₇₀ versus D300:C₇₀ can vary between, for example, a thickness ratio of 1:99 to 99:1, among other possibilities.

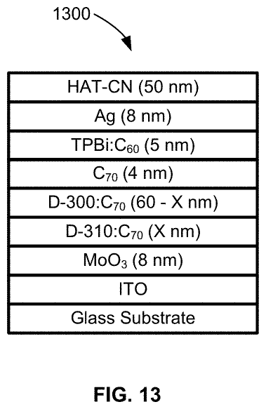

FIG. 13 illustrates a device structure 1300 of a stacked BHJ with constant overall thickness but varying thickness of the two constituent BHJ layers. The ITO layer, the MoO₃ layer, the Ag layer, and the TPBi:C₆₀ layer constitute electrode and buffer layers as described above. The thickness of D-310:C₇₀ is equal to the variable X (nm), while the thickness of D-300:C₇₀ is equal to 60−X (nm). Accordingly, in various embodiments, the thicknesses of D-310:C₇₀ and D-300:C₇₀ can each vary between 0 and 60 nm, while the thickness of device structure 1300 remains constant. In some examples, the donor to acceptor ratio can be maintained at 50:50 by volume for each of the BHJ layers D-310:C₇₀ and D-300:C₇₀.

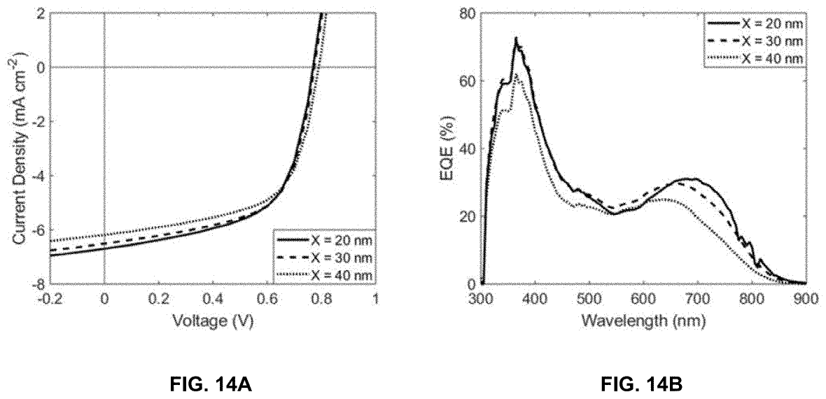

FIGS. 14A and 14B illustrate current density-voltage (FIG. 14A) and EQE curves (FIG. 14B) for device structure 1300 shown in FIG. 13, where X is varied from 20 to 40 nm. As is evident from the EQE curves, the spectral response can be tuned by the thickness of the BHJ layers. As thickness is varied, the overall content of each donor is linearly adjusted within the active layers, and the EQE peak is shifted between the binary BHJ responses of D-300:C₇₀ or D-310:C₇₀ (shown in FIG. 12B). This can be equivalent to adjusting the ratio of donor molecules in a ternary blend.

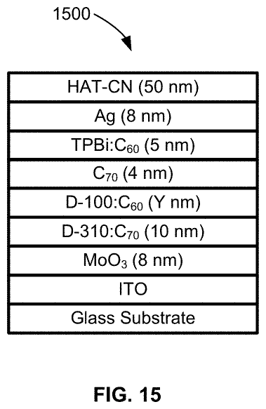

FIG. 15 illustrates a device structure 1500 of a stacked BHJ employing a varying thickness of the NIR-absorbing BHJ layer and a fixed thickness of the visibly absorbing BHJ layer. The ITO layer, the MoO₃ layer, the Ag layer, and the TPBi:C₆₀ layer constitute electrode and buffer layers as described above. The thickness of D-100:C₆₀ is equal to the variable Y (nm). Accordingly, in various embodiments, the thickness of device structure 1500 can vary based on the thickness of D-100:C₆₀. In some embodiments, the thickness of D-100:C₆₀ is equal 10 nm, 20 nm, 30 nm, or 40 nm. The donor to acceptor ratio can be maintained at 50:50 and 20:80 by volume for D-310:C₇₀ and D-100:C₆₀, respectively.

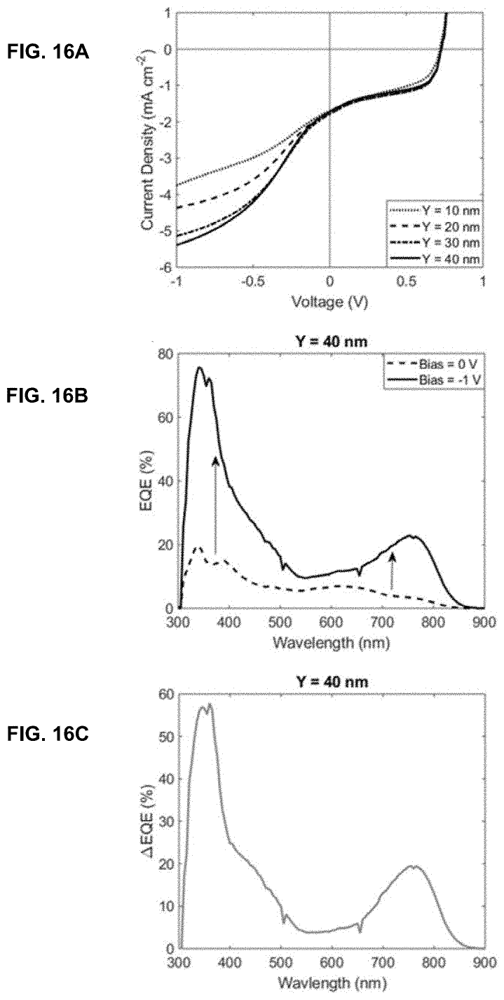

FIGS. 16A-16C illustrate current density-voltage (FIG. 16A) and EQE curves (FIG. 16B) for device structure 1500 shown in FIG. 15, where Y is varied from 10 to 40 nm. Due to improper HOMO level alignment between the D-310 and D-100 donors, the D-310:C₇₀ layer presents an extraction barrier for holes generated within the D-100:C₆₀ layer. As a result, charge carriers generated within the D-100:C₆₀ BHJ are unable to be extracted under forward bias. This leads to the “s-shaped kinks” in I-V curves. Applying a high reverse bias (−0.5 V to −1 V) drives these carriers over the extraction barrier and yields the nominal photocurrent from the stack. As can be seen in FIG. 16B, the EQE at high reverse bias (−1 V) is significantly higher than at zero bias, which is dominated by photocurrent from the thin D310:C₇₀ BHJ layer. The EQE difference between 0 V and −1 V applied bias is shown in FIG. 16C for the case where Y is equal to 40 nm, matching the photocurrent output expected from D-100:C₆₀ (FIG. 10B).

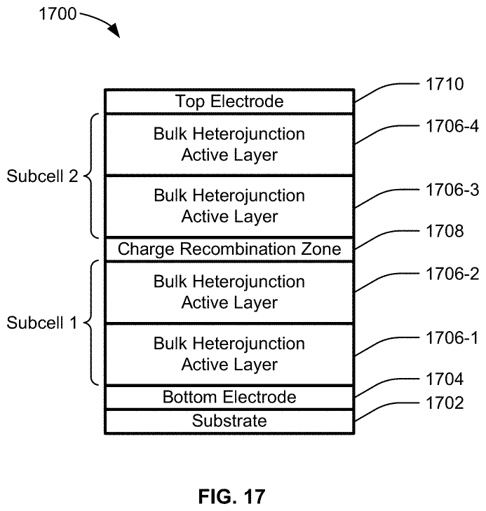

FIG. 17 illustrates a device structure 1700 showing an extension of the stacked BHJ concept to a series tandem architecture. In this case, a series tandem is formed between two subcells (“Subcell 1” and “Subcell 2”), each of which consists of stacked BHJs 1706, connected through a charge recombination zone 1708. The two subcells are stacked between a top electrode 1710 and a bottom electrode 1704, which may be formed on a substrate 1702. This concept may include any number of subcells, each of which may be comprised of any number of stacked BHJs. The spectral tunability afforded by the stacked BHJs in each subcell increases the design flexibility of the series tandem, as current matching can be better tailored between subcells.

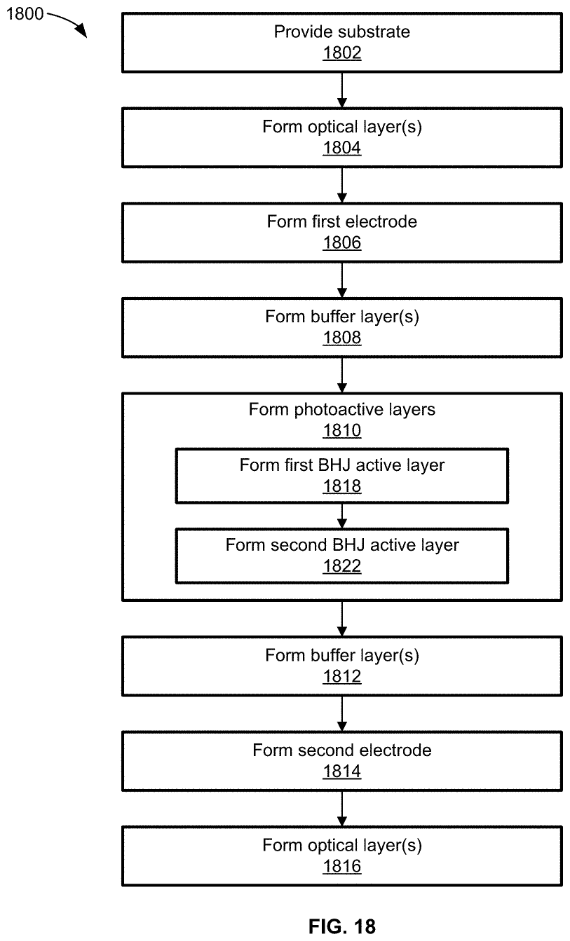

FIG. 18 illustrates a method 1800 for making a photovoltaic device, such as visibly transparent photovoltaic device 100, device structures 600, 900, 1100, 1300, 1500, 1700, or any combinations thereof. In various embodiments, the photovoltaic device may be visibly transparent or may be non-visibly transparent or opaque. For example, any of the components of the photovoltaic device described in reference to method 1800 may be non-visibly transparent, such as an opaque first electrode (at block 1806) or an opaque second electrode (at block 1814). Furthermore, any of the components described in reference to method 1800 as being visibly transparent may, in some embodiments, be non-visibly transparent or opaque. Method 1800 may include additional or fewer steps than is illustrated in FIG. 18. Furthermore, one or more steps of method 1800 may be performed in a different order than is illustrated in FIG. 18.

Method 1800 begins at block 1802, where a substrate is provided, such as, e.g., a transparent substrate. It will be appreciated that useful transparent substrates include visibly transparent substrates, such as glass, plastic, quartz, and the like. Flexible and rigid substrates are useful with various embodiments. Optionally, the transparent substrate is provided with one or more optical layers preformed on top and/or bottom surfaces.

At block 1804, one or more optical layers are optionally formed on or over the transparent substrate, such as on top and/or bottom surfaces of the transparent substrate. Optionally, the one or more optical layers are formed on other materials, such as an intervening layer or material, such as a transparent conductor. Optionally, the one or more optical layers are positioned adjacent to and/or in contact with the visibly transparent substrate. It will be appreciated that formation of optical layers is optional, and some embodiments may not include optical layers adjacent to and/or in contact with the transparent substrate. Optical layers may be formed using a variety of methods including, but not limited to, one or more chemical deposition methods, such as plating, chemical solution deposition, spin coating, dip coating, slot-die coating, blade coating, spray coating, chemical vapor deposition, plasma enhanced chemical vapor deposition, and atomic layer deposition, or one or more physical deposition methods, such as thermal evaporation, electron beam evaporation, molecular beam epitaxy, sputtering, pulsed laser deposition, ion beam deposition, and electrospray deposition. It will be appreciated that useful optical layers include visibly transparent optical layers. Useful optical layers include those that provide one or more optical properties including, for example, antireflection properties, wavelength selective reflection or distributed Bragg reflection properties, index matching properties, encapsulation, or the like. Useful optical layers may optionally include optical layers that are transparent to ultraviolet and/or near-infrared light. Depending on the configuration, however, some optical layers may optionally provide passive infrared and/or ultraviolet absorption. Optionally, an optical layer may include a visibly transparent photoactive compound described herein.

At block 1806, a first (e.g., bottom) electrode is formed, such as, e.g., a first transparent electrode. As described above, the transparent electrode may correspond to an ITO thin film or other transparent conducting film, such as thin metal films (e.g., Ag, Cu, etc.), multilayer stacks comprising thin metal films (e.g., Ag, Cu, etc.) and dielectric materials, or conductive organic materials (e.g., conducting polymers, etc.). It will be appreciated that transparent electrodes include visibly transparent electrodes. Transparent electrodes may be formed using one or more deposition processes, including vacuum deposition techniques, such as atomic layer deposition, chemical vapor deposition, physical vapor deposition, thermal evaporation, sputter deposition, epitaxy, etc. Solution based deposition techniques, such as spin-coating, may also be used in some cases. In addition, transparent electrodes may be patterned by way of microfabrication techniques, such as lithography, lift off, etching, etc.

At block 1808, one or more buffer layers are optionally formed, such as on the transparent electrode. Buffer layers may be formed using a variety of methods including, but not limited to, one or more chemical deposition methods, such as a plating, chemical solution deposition, spin coating, dip coating, chemical vapor deposition, plasma enhanced chemical vapor deposition, and atomic layer deposition, or one or more physical deposition methods, such as thermal evaporation, electron beam evaporation, molecular beam epitaxy, sputtering, pulsed laser deposition, ion beam deposition, and electrospray deposition. It will be appreciated that useful buffer layers include visibly transparent buffer layers. Useful buffer layers include those that function as electron transport layers, electron blocking layers, hole transport layers, hole blocking layers, optical spacers, physical buffer layers, charge recombination layers, or charge generation layers. In some cases, the disclosed visibly transparent photoactive compounds may be useful as a buffer layer material. For example, a buffer layer may optionally include a visibly transparent photoactive compound described herein.

At block 1810, one or more photoactive layers are formed, such as on a buffer layer or on a transparent electrode. As described above, the photoactive layers may comprise electron acceptor layers and electron donor layers or co-deposited layers of electron donors and acceptors.

Photoactive layers may be formed using a variety of methods including, but not limited to, one or more chemical deposition methods, such as a plating, chemical solution deposition, spin coating, dip coating, chemical vapor deposition, plasma enhanced chemical vapor deposition, and atomic layer deposition, or one or more physical deposition methods, such as thermal evaporation, electron beam evaporation, molecular beam epitaxy, sputtering, pulsed laser deposition, ion beam deposition, and electrospray deposition.

In some embodiments, block 1810 may include forming one or more BHJ active layers. For example, at block 1818, a first BHJ active layer is formed. In some embodiments, the first BHJ active layer is formed on the first transparent electrode formed at block 1806 or on the buffer layer formed at block 1808. The first BHJ active layer may comprise a blend (i.e., first blend) of an electron donor material (i.e., first electron donor material) and an electron acceptor material (i.e., first electron acceptor material). The first BHJ active layer may have a HOMO energy level (i.e., first HOMO energy level) that is characterized by (e.g., equal to) a HOMO energy level of the first electron donor material, and a LUMO energy level (i.e., first LUMO energy level) that is characterized by (e.g., equal to) a LUMO energy level of the first electron acceptor material.

The first BHJ active layer may be a binary, ternary, quaternary, or a higher-order blend of electron donor materials (including the first electron donor material) and electron acceptor materials (including the first electron acceptor material). The first BHJ active layer may be coated by an exciton-blocking layer, a hole-blocking layer, or an electron-blocking layer. In some embodiments, an exciton-blocking layer, a hole-blocking layer, or an electron-blocking layer is disposed (e.g., deposited) between the first BHJ active layer and the first transparent electrode.

As another example, at block 1820, a second BHJ active layer is formed. In some embodiments, the second BHJ active layer is formed on the first BHJ active layer formed at block 1818. The second BHJ active layer may comprise a blend (i.e., second blend) of an electron donor material (i.e., second electron donor material) and an electron acceptor material (i.e., second electron acceptor material). The second BHJ active layer may have a HOMO energy level (i.e., second HOMO energy level) that is characterized by (e.g., equal to) a HOMO energy level of the second electron donor material, and a LUMO energy level (i.e., second LUMO energy level) that is characterized by (e.g., equal to) a LUMO energy level of the second electron acceptor material.

The second BHJ active layer may be a binary, ternary, quaternary, or a higher-order blend of electron donor materials (including the second electron donor material) and electron acceptor materials (including the second electron acceptor material). The second BHJ active layer may be coated by an exciton-blocking layer, a hole-blocking layer, or an electron-blocking layer. In some embodiments, an exciton-blocking layer, a hole-blocking layer, or an electron-blocking layer is disposed between the second BHJ active layer and a second transparent electrode.

In some embodiments, the first BHJ active layer may have a distinct electron donor material from the second BHJ active layer (e.g., the first electron donor material may be different than the second electron donor material). In some embodiments, the first BHJ active layer may share an electron donor material with the second BHJ active layer (e.g., the first electron donor material may be the same as the second electron donor material). In some embodiments, the first BHJ active layer may have a distinct electron acceptor material from the second BHJ active layer (e.g., the first electron acceptor material may be different than the second electron acceptor material). In some embodiments, the first BHJ active layer may share an electron acceptor material with the second BHJ active layer (e.g., the first electron acceptor material may be the same as the second electron acceptor material).

In various embodiments, the first LUMO energy level and the second LUMO energy level may be within 100 meV, 200 meV, 300 meV, 400 meV, or 500 meV of each other. In various embodiments, the first HOMO energy level and the second HOMO energy level may be within 100 meV, 200 meV, 300 meV, 400 meV, or 500 meV of each other.

In some embodiments, the first BHJ active layer may have one or more peak absorption wavelengths, which are wavelengths where the absorption of radiation by the first BHJ active layer exhibits a peak. In some embodiments, the second BHJ active layer may have one or more peak absorption wavelengths, which are wavelengths where the absorption of radiation by the second BHJ active layer exhibits a peak. In some embodiments, the absorption spectrum of the first BHJ active layer is at least partially complementary to the absorption spectrum of the second BHJ active layer. In such embodiments, the peak absorption wavelength of the first BHJ active layer is offset from the peak absorption wavelength of the second BHJ active layer by at least a wavelength offset amount so as to provide broader spectral coverage. In various embodiments, the wavelength offset amount may be 50 nm, 100 nm, 150 nm, 200 nm, 250 nm, 300 nm, 350 nm, or any value there between.

At block 1812, one or more buffer layers are optionally formed, such as on the photoactive layer. The buffer layers formed at block 1812 may be formed similar to those formed at block 1808.

At block 1814, a second (e.g., top) electrode is formed, such as, e.g., a second transparent electrode. The second transparent electrode may be formed on a buffer layer or on a photoactive layer. The second transparent electrode may be formed using techniques applicable to formation of first transparent electrode at block 1806.

At block 1816, one or more additional optical layers are optionally formed, such as on the second transparent electrode.

Method 1800 may optionally be extended to correspond to a method for generating electrical energy. For example, a method for generating electrical energy may comprise providing a visibly transparent photovoltaic device, such as by making a visibly transparent photovoltaic device according to method 1800. Methods for generating electrical energy may further comprise exposing the visibly transparent photovoltaic device to visible, ultraviolet and/or near-infrared light to drive the formation and separation of electron-hole pairs, for example, for generation of electrical energy. The visibly transparent photovoltaic device may include the visibly transparent photoactive compounds described herein as photoactive materials, buffer materials, and/or optical layers.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. Any recitation herein of the term “comprising”, particularly in a description of components of a composition or in a description of elements of a device, is understood to encompass those compositions and methods consisting essentially of and consisting of the recited components or elements. The invention illustratively described herein suitably may be practiced in the absence of any element or elements, limitation or limitations which is not specifically disclosed herein.

Abbreviations that may be utilized in the present specification include:
TPBi: 2,2′,2″-(1,3,5-Benzinetriyl)-tris(1-phenyl-1-H-benzimidazole)
HAT-CN: Dipyrazino[2,3-f :2′,3′-h]quinoxaline-2,3 ,6,7,10,11-hexacarbonitrile
PTCBI: Bisbenzimidazo[2,1-a :1′,2-b′ ]anthra[2,1,9-def :6,5,10-d′eT]diisoguinoline-10,21-dione
DBP: Dibenzo{[f,f′]-4,4′,7,7′-tetraphenyl}diindeno[1,2,3-cd: 1′,2′,3′-lm]perylene

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed.

Thus, it should be understood that although the present invention has been specifically disclosed by preferred embodiments and optional features, modification and variation of the concepts herein disclosed may be resorted to by those skilled in the art, and that such modifications and variations are considered within the scope of this invention as defined by the appended claims.

What is claimed is:

1. An organic photovoltaic device comprising:
a substrate;
a first electrode coupled to the substrate;
a second electrode disposed above the first electrode;
a first bulk heterojunction (BHJ) active layer disposed between the first electrode and the second electrode, wherein the first BHJ active layer comprises a first blend of a first electron donor material and a first electron acceptor material; and
a second BHJ active layer disposed between the first electrode and the second electrode, wherein the second BHJ active layer comprises a second blend of a second electron donor material and a second electron acceptor material, and wherein the second BHJ active layer is in contact with the first BHJ active layer;
wherein an absorption spectrum of the first BHJ active layer is at least partially complementary to an absorption spectrum of the second BHJ active layer.

2. The organic photovoltaic device of claim 1, wherein the first electron donor material is different than the second electron donor material, and wherein the first electron acceptor material is different than the second electron acceptor material.

3. The organic photovoltaic device of claim 1, wherein the first electron donor material is different than the second electron donor material, and wherein the first electron acceptor material is the same as the second electron acceptor material.

4. The organic photovoltaic device of claim 1, wherein the first electron donor material is the same as the second electron donor material, and wherein the first electron acceptor material is different than the second electron acceptor material.

5. The organic photovoltaic device of claim 1, wherein the first electron donor material is the same as the second electron donor material, and wherein the first electron acceptor material is the same as the second electron acceptor material.

6. The organic photovoltaic device of claim 1, wherein a lowest unoccupied molecular orbital (LUMO) energy level of the first BHJ active layer is greater than a LUMO energy level of the second BHJ active layer.

7. The organic photovoltaic device of claim 1, wherein a highest occupied molecular orbital (HOMO) energy level of the second BHJ active layer is less than a HOMO energy level of the first BHJ active layer.

8. The organic photovoltaic device of claim 1, wherein a lowest unoccupied molecular orbital (LUMO) energy level of the first electron acceptor material of the first BHJ active layer is within 300 meV of a LUMO energy level of the second electron acceptor material of the second BHJ active layer.

9. The organic photovoltaic device of claim 1, wherein a highest occupied molecular orbital (HOMO) energy level of the first electron donor material of the first BHJ active layer is within 300 meV of a HOMO energy level of the second electron donor material of the second BHJ active layer.

10. The organic photovoltaic device of claim 1, wherein the first BHJ active layer is coupled to the second BHJ active layer.

11. The organic photovoltaic device of claim 1, wherein the first blend is a ternary, quaternary, or higher-order blend that includes at least one of an additional electron donor material or an additional electron acceptor material.

12. The organic photovoltaic device of claim 1, wherein the second blend is a ternary, quaternary, or higher-order blend that includes at least one of an additional electron donor material or an additional electron acceptor material.

13. The organic photovoltaic device of claim 1, wherein the first BHJ active layer is coupled to the first electrode.

14. The organic photovoltaic device of claim 1, wherein the second BHJ active layer is coupled to the second electrode.

15. An organic photovoltaic device comprising:
a visibly transparent substrate;
a first visibly transparent electrode coupled to the visibly transparent substrate;
a second visibly transparent electrode disposed above the first visibly transparent electrode;
a first bulk heterojunction (BHJ) active layer disposed between the first visibly transparent electrode and the second visibly transparent electrode, wherein the first BHJ active layer comprises a first blend of a first electron donor material and a first electron acceptor material; and
a second BHJ active layer disposed between the first visibly transparent electrode and the second visibly transparent electrode, wherein the second BHJ active layer comprises a second blend of a second electron donor material and a second electron acceptor material, and wherein the second BHJ active layer is in contact with the first BHJ active layer;
wherein an absorption spectrum of the first BHJ active layer is at least partially complementary to an absorption spectrum of the second BHJ active layer.

16. A tandem organic photovoltaic device comprising:
a substrate;
a first electrode coupled to the substrate;
a second electrode disposed above the first electrode;
a first subcell disposed between the first electrode and the second electrode, the first subcell comprising:
a first bulk heterojunction (BHJ) active layer comprising a first blend of a first electron donor material and a first electron acceptor material; and
a second BHJ active layer comprising a second blend of a second electron donor material and a second electron acceptor material, wherein the second BHJ active layer is in contact with the first BHJ active layer, and wherein an absorption spectrum of the first BHJ active layer is at least partially complementary to an absorption spectrum of the second BHJ active layer;
a second subcell disposed between the first electrode and the second electrode, the second subcell comprising:
a third BHJ active layer comprising a third blend of a third electron donor material and a third electron acceptor material; and
a charge recombination zone disposed between the first subcell and the second subcell.

17. The tandem organic photovoltaic device of claim 16, wherein the first subcell is disposed between the first electrode and the charge recombination zone.

18. The tandem organic photovoltaic device of claim 16, wherein the second subcell is disposed between the first electrode and the charge recombination zone.

19. The tandem organic photovoltaic device of claim 16, wherein the second subcell further comprises a fourth BHJ active layer comprising a fourth blend of a fourth electron donor material and a fourth electron acceptor material, wherein the fourth BHJ active layer is in contact with the third BHJ active layer, and wherein the absorption spectrum of the fourth BHJ active layer is at least partially complementary to the absorption spectrum of the third BHJ active layer.

20. The tandem organic photovoltaic device of claim 16, wherein the tandem organic photovoltaic device is visibly transparent.
